(19) United States
(12) Patent Application Publication
(10) Pub. No.: US 2025/0055431 A1
(43) Pub. Date: Feb. 13, 2025

(54) OFFSET CALIBRATION FOR SIGNAL RMS MEASUREMENT

(71) Applicant: MACOM Technology Solutions Holdings, Inc., Lowell, MA (US)

(72) Inventors: Jonathan Ugolini, Lowell, MA (US); Biagio Bisanti, Lowell, MA (US)

(21) Appl. No.: 18/230,767

(22) Filed: Aug. 7, 2023

(51) Int. Cl. H03F 3/45; H03F 1/26

(52) U.S. Cl. CPC H03F 3/45744; H03F 1/26; H03F 3/45188; H03F 2200/261

(57) ABSTRACT

Offset calibration for signal rms measurement is provided. A method includes determining a first offset calibration of a first differential pair of a circuit. The first differential pair comprises a first transistor and a second transistor. The method also includes determining a second offset calibration of a second differential pair of the circuit. The second differential pair comprises a third transistor and a fourth transistor. Further, the method includes, based on the first offset calibration and the second offset calibration, determining a third offset calibration of a common mode.

### TECHNICAL FIELD

The subject disclosure relates generally to electrical circuit calibration.

### BACKGROUND

An electronic signal receiver adapts its gain according to the strength of the received signal. A Room Mean Square (RMS) detector circuit provides information to the receiver about the strength of the received signal. However, the direct current (DC) offset of the RMS detector limits the dynamic of the measurable signal. For example, if the signal is too weak, its RMS value is comparable to the DC offset of the detector. Therefore, the measurement is useless. Accordingly, unique challenges exist related to detector calibration.

It is noted that the above-described description is merely intended to provide a contextual overview of RMS detector design and is not intended to be exhaustive.

### SUMMARY

The following presents a simplified summary in order to provide a basic understanding of some aspects described herein. This summary is not an extensive overview of the disclosed subject matter. It is intended to neither identify key nor critical elements of the disclosure nor delineate the scope thereof. Its sole purpose is to present some concepts in a simplified form as a prelude to the more detailed description that is presented later.

In one or more embodiments, provided is a method that includes determining a first offset calibration of a first differential pair of a circuit. The first differential pair comprises a first transistor and a second transistor. The method also includes determining a second offset calibration of a second differential pair of the circuit. The second differential pair comprises a third transistor and a fourth transistor. Further, the method includes, based on the first offset calibration and the second offset calibration, determining a third offset calibration of a common mode. The common mode comprises a combination of the first differential pair and the second differential pair. In an example, determining the first offset calibration, determining the second offset calibration, and determining the third offset calibration can be performed by a comparator.

According to some implementations, determining the first offset calibration can include comparing a first current at a positive side of the first differential pair and a second current at a negative side of the first differential pair. Further to these implementations, determining the second offset calibration comprises comparing a third current at a positive side of the second differential pair and a fourth current at a negative side of the second differential pair.

In some implementations determining the first offset calibration, determining the second offset calibration, and determining the third offset calibration can include controlling respective back gate biases of the first transistor and the second transistor of the first differential pair and the third transistor and the fourth transistor of the second differential pair.

According to some implementations, determining the first offset calibration can include determining the first offset calibration during a first time period when no signals are applied at the first differential pair. Further to these implementations, determining the second offset calibration can include determining the second offset calibration during a second time period when no signals are applied at the second differential pair.

In an example, a bias current is shared by the first differential pair and the second differential pair. According to another example, the first differential pair is configured to receive a reference level voltage and the second differential pair is configured to receive a signal. The reference level voltage is a DC voltage, and the signal is an alternating voltage.

The method can include, according to some implementations, biasing the circuit using a constant to absolute temperature (Ctat) current. In alternative or additional implementations, the method can include biasing the circuit using a proportional to absolute temperature (Ptat) current.

In some implementations, the method can include storing the first offset calibration in a first memory structure and storing the second offset calibration in a second memory structure. Further, the third offset calibration and/or other offset calibrations can be stored in respective memory structures.

Another embodiment relates to a method that includes calibrating a first differential pair of a peak detector circuit. The method also includes calibrating a second differential pair of the peak detector circuit independent of the calibrating of the first differential pair. Further, the method includes calibrating a common mode of the peak detector circuit.

Calibrating of the first differential pair can include incrementing a first defined value of a first input of the first differential pair until a first comparator output toggles. Further, a first result of the incrementing of the first defined value of the first input can be stored in a first memory. Additionally, the method can include changing a first indicator of the first differential pair from a first amount to a second amount. The second amount identifies a completion of a first calibration of the first differential pair.

Further, calibrating of the second differential pair can include incrementing a second defined value of a second reference of the second differential pair until a second comparator output toggles. A second result of the incrementing of the second defined value of the second reference can be stored in a second memory. Additionally, the method can include changing a second indicator of the second differential pair from a third value to a fourth value. The fourth value identifies a second completion of a second calibration of the second differential pair.

In an example, the method can include biasing the peak detector circuit using a proportional to absolute temperature (Ptat) current. Alternatively, or additionally the method can include biasing the peak detector circuit using a constant to absolute temperature (Ctat) current.

According to an implementation, calibrating the first differential pair can include determining a first offset calibration of the first differential pair during a first time period when no signals are applied at the first differential pair. Further, calibrating the second differential pair can include determining a second offset calibration of the second differential pair during a second time period when no signals are applied at the second differential pair.

In some implementations, the method can include retaining the first offset calibration in a first memory and retaining the second offset calibration in a second memory. The first memory and the second memory can be different memories.

The method can include, according to some implementations, controlling a back gate bias of a first transistor and a second transistor of the first differential pair and a third transistor and a fourth transistor of the second differential pair.

In some implementations, calibrating the first differential pair can include comparing a first current at a positive side of the first differential pair and a second current at a negative side of the first differential pair. Further to these implementations, calibrating the second differential pair can include comparing a third current at a positive side of the second differential pair and a fourth current at a negative side of the second differential pair.

### BRIEF DESCRIPTION OF THE DRAWINGS

FIG. 1 illustrates an example, non-limiting, diagram of a peak detector circuit in accordance with one or more embodiments described herein.

FIG. 2 illustrates an example, non-limiting, graph of results for a measurement in accordance with one or more embodiments described herein.

FIG. 3 illustrates an equation for measurements associated with the graph of FIG. 2.

FIG. 4 illustrates an example, non-limiting, block diagram of automatic gain control loop building blocks in accordance with one or more embodiments described herein.

FIGS. 5A-5C illustrate example, non-limiting, representations of calibrations for a first differential pair, a second differential pair, and a common mode in accordance with one or more embodiments described herein.

FIG. 6 illustrates an example, non-limiting, flow diagram of a method that facilitates offset calibration for signal rms measurement in accordance with one or more embodiments described herein.

FIG. 7 illustrates an example, non-limiting, flow diagram for a method for calibration of a first differential pair in accordance with one or more embodiments described herein.

FIG. 8 illustrates an example, non-limiting, flow diagram for a method for calibration of a second differential pair in accordance with one or more embodiments described herein.

### DETAILED DESCRIPTION

The disclosure herein is described with reference to the drawings, wherein like reference numerals are used to refer to like elements throughout. In the following description, for purposes of explanation, numerous specific details are set forth in order to provide a thorough understanding of the subject innovation. It may be evident, however, that various disclosed aspects can be practiced without these specific details. In other instances, well-known structures and devices are shown in block diagram form in order to facilitate describing the subject innovation.

As previously mentioned, an electronic signal receiver adapts its gain according to the strength of the received signal. A Root Mean Square (RMS) detector circuit provides information to the receiver about the strength of the received signal. Unfortunately, the direct current (DC) offset of the RMS detector limits the dynamic of the measurable signal. For example, if the signal is too weak, its RMS value is comparable to the DC offset of the detector. Therefore, the measurement is useless. The embodiments discussed herein allow for calibration of the DC offset of the RMS detector.

Traditionally, the above noted problem has been addressed by pre-amplifying the signal before measuring the signal using the RMS detector. In some cases, this requires a dedicated amplifier outside the main signal path, which might not be practical.

As discussed herein, the RMS detector is implemented using a squarer cell. According to an implementation, the squarer cell can be designed in a CMOS technology. However, any type of technology can be utilized with the disclosed embodiments. The offset calibration is implemented by controlling the BACK GATE of the gain transistors of the squarer cell. Further, the disclosed embodiments can mitigate the need to use a dedicated gain stage.

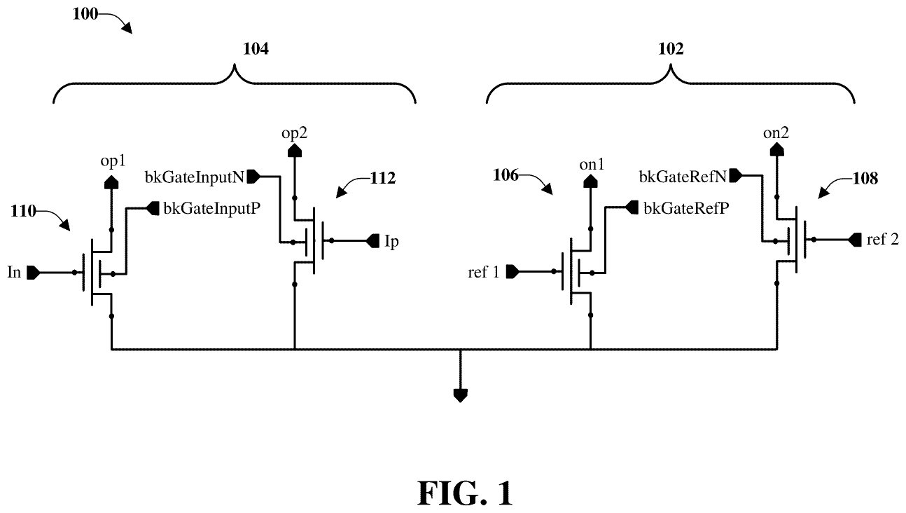

FIG. 1 illustrates an example, non-limiting, diagram of a peak detector circuit 100 in accordance with one or more embodiments described herein. It is noted that the peak detector circuit 100 illustrated in FIG. 1 is a simplified circuit, as some components not necessary for understanding the circuit may have been omitted for sake of brevity.

Peak detector circuits can be utilized to determine a maximum (or peak) value of an input signal. In operation, the peak detector circuit can store the maximum (or peak) value of the input voltages for various time durations (e.g., until a reset condition occurs, or at some other time).

As illustrated, the peak detector circuit 100 includes two differential pairs, illustrated as a first differential pair 102 and a second differential pair 104. The first differential pair 102 includes a first transistor 106 and a second transistor 108. The second differential pair 104 includes a third transistor 110 and a fourth transistor 112. It is noted that as utilized herein, terms such as “first,” “second,” “third,” “fourth,” and so on are used to distinguish elements having a same name from one another.

The two differential pairs (e.g., the first differential pair 102, the second differential pair 104) share the same bias current. For example, the bias current (Ibias) can be 140 micro amps (140 μA). However, another value for the bias current can be utilized with the embodiments discussed herein.

One input can be dedicated to reference level (DC), illustrated as inputs ref1 and ref2 of the first differential pair 102. A second input can receive the signal (AC), illustrated as positive current (Ip) and negative current (In) of the second differential pair 104. Further, the circuit output is a differential current that can be measured by a cascaded amplifier.

The precision of the peak detector circuit 100 can be limited by the mismatch between the two differential pairs. Accordingly, calibration of the peak detector circuit 100 should be performed. The differential pairs can be calibrated by controlling the back gate bias of the four input transistors (e.g., the first transistor 106, the second transistor 108, the third transistor 110, and the fourth transistor 112). It is noted that the calibration can be performed when there are no signals being applied (e.g., the reference voltage is equal to zero volts (Vreference=0 volts)).

According to an implementation, the peak detector circuit 100 can be biased using a constant to absolute temperature (Ctat) current. In an alternative or additional implementation, the peak detector circuit 100 can be biased using a proportional to absolute temperature (Ptat) current.

Various measurements can be performed. For example, the Gm of the differential pair due to the input differential signal can be measured. The Gmbk of the differential pair due to the back gate differential bias can be measured. Further, the offset current of the differential pair can be measured.

In other words, a first offset of the first differential pair can be determined. Separately, a second offset of the second differential pair can be determined. Upon or after the first offset and the second offset are determined, the offset of both the first differential pair and the second differential pair, in combination, can be determined.

In an implementation, a bias current can be shared by the first differential pair 102 and the second differential pair 104. In another example, the first differential pair 102 can be configured to receive a DC voltage as a reference and the second differential pair 104 can be configured to receive an alternating voltage as a signal.

A product implementing the disclosed embodiments can have a start-up calibration phase that can be enabled any time there is a change in the operating conditions. For example, the start-up calibration phase can be enabled based on detection of a change to an operating temperature, a supply voltage, and/or other parameters for which calibration would be beneficial.

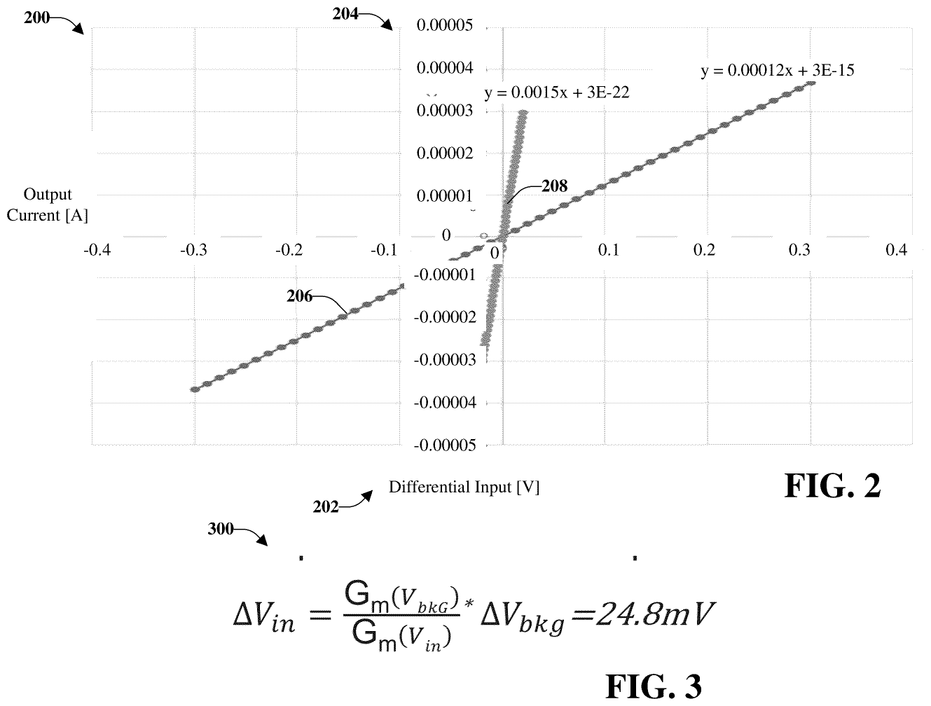

FIG. 2 illustrates an example, non-limiting, graph 200 of results for a measurement in accordance with one or more embodiments described herein. More specifically, the graph illustrates output current versus input differential voltage and versus back gate differential voltage.

The output current [A] is represented on the vertical axis 202. The differential input [V] is represented on the horizontal axis 204. Line 206 represents the output current versus the diff-input. Line 208 represents the output current verses the back-gate.

It is noted that the various measurements discussed herein are for example purposes in order to describe the various embodiments. In implementation, other measurements and/or results can be realized.

As illustrated, for this example, Gₘ(V_{bkG}) is equal to about 120 μA/V. Further, Gₘ(Vin) is equal to around 1.5 mA/V. Using ΔV_{bkG} being equal to 300 mV, it can be possible to compensate 25 mV of input offset, as indicated in equation 300 of FIG. 3. Using 5-bit resolution on ΔV_{bkG} being equal to or more than 9.7 mv, the input offset resolution can be equal to or more than 0.8 mv.

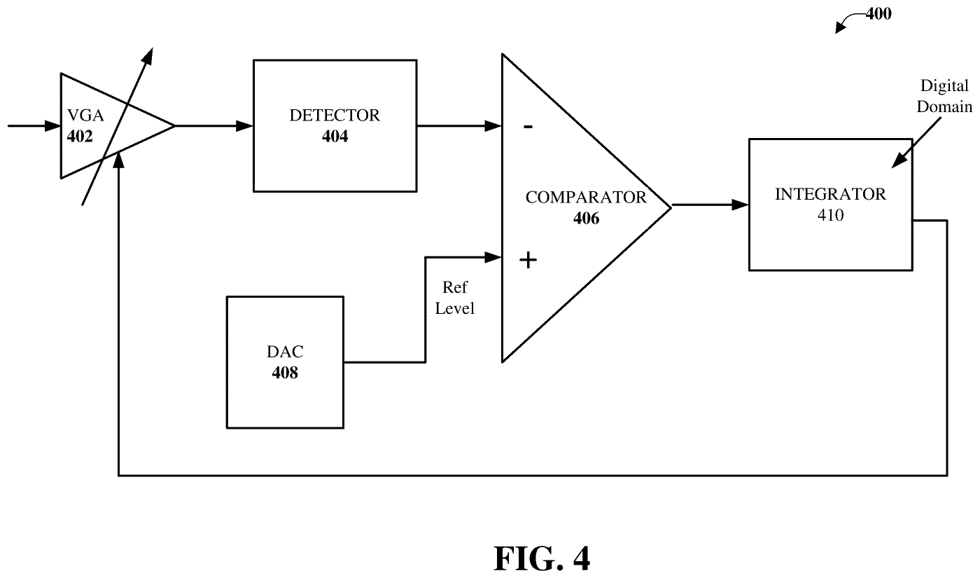

FIG. 4 illustrates an example, non-limiting, block diagram of automatic gain control (AGC) loop building blocks 400 in accordance with one or more embodiments described herein. The loop building blocks 400 can include a Variable Gain Amplifier (VGA 402), a detector 404, a comparator 406, a Digital to Analog Converter (DAC 408), and an integrator 410. The VGA 402 provides input to a detector 404, which sends data to the comparator 406. The comparator 406 also receives data from the DAC 408. An output of the comparator 406 can be sent to the integrator 410, which outputs information that is fed back to the VGA 402. In a specific implementation, the section of the squarer identified by the transistors 106 and 108, as a function of the reference branch and the DAC output (voltage), is the input for the differential pair 106-108.

The current coming out of differential pairs of the detector 404 (e.g., a peak detector) goes into one or more switches of a set of switches (not shown). Based upon selection of a switch from the set of switches, the current coming from the peak detector can be selected. The offset can be calibrated by comparing the current coming from the positive side and the negative side of the differential pair.

The result can be input into the comparator 406, which compares the current and serves the output high or low depending on which one of the currents is a higher value. When the comparator changes polarity, it indicates that the calibration is performed with the precision limit of the DAC controlling the back gate of the differential diff-pair under test.

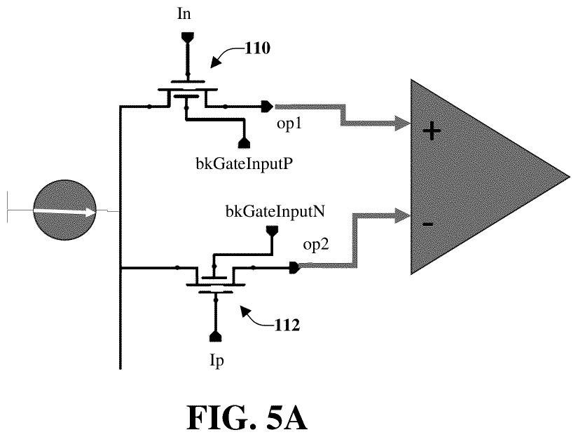

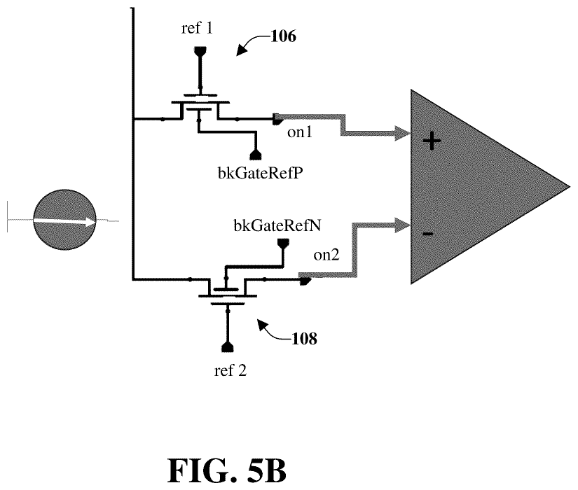

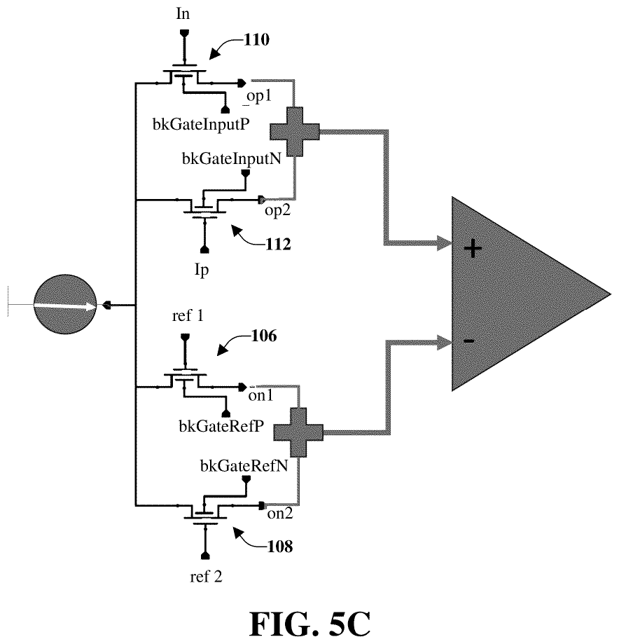

FIGS. 5A-5C illustrate example, non-limiting, representations of calibrations for a first differential pair (FIG. 5A), a second differential pair (FIG. 5B), and a common mode (FIG. 5C) in accordance with one or more embodiments described herein. Repetitive description of like elements employed in other embodiments described herein is omitted for sake of brevity.

With reference to FIG. 5A, at a beginning of a calibration procedure, Ip-In is equal to zero volts (0 V), thus, there is no input signal. The bkGateInputP and bkGateInputN are equal to the DAC output. Further, op1 and op2 are connected to a comparator (e.g., a current comparator) while on1 and on2 are left floating (e.g., open circuit). Upon or after the comparator toggles, the calibration is achieved with an amount of precision allowed by the DAC resolution.

A similar procedure is followed for the second differential pair. For example, with reference to FIG. 5B, Ref1-Ref2 is equal to zero volts, thus, there is no input signal. Further, on1 and on2 are connected to the comparator (e.g., a current comparator) while op1 and op2 are left floating (e.g., open circuit). In addition, backGateRefP-bkGateRefN is equal to the DAC output. Upon or after the comparator toggles, the calibration is achieved with the amount of precision allowed by the DAC resolution.

To calibrate the Common Mode (op1 shorted with op2 and on1 shorted with on2). The DAC controls the differential voltage between the common mode of the differential pairs previously calibrated. The calibration values of the first and second differential pair should not change during the common mode calibration.

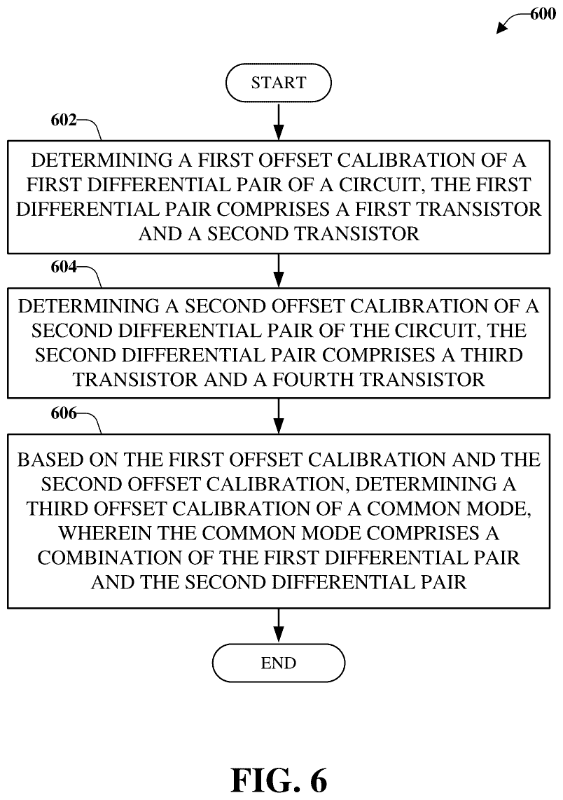

FIG. 6 illustrates an example, non-limiting, flow diagram of a method 600 that facilitates offset calibration for signal rms measurement in accordance with one or more embodiments described herein.

The method 600 starts at 602, with determination of a first offset calibration of a first differential pair of a circuit. The first differential pair comprises a first transistor and a second transistor. For example, the first differential pair can be associated with an input signal. Determining the first offset calibration can include comparing a first current at a positive side of the first differential pair and a second current at a negative side of the first differential pair.

At 604, a second offset calibration of a second differential pair of the circuit is determined. The second differential pair comprises a third transistor and a fourth transistor. For example, the second differential pair can be associated with a reference. Determining the first offset calibration at 602 and determining the second offset calibration at 604 are performed separately or individually for each differential pair. Determining the second offset calibration can include comparing a third current at a positive side of the second differential pair and a fourth current at a negative side of the second differential pair.

Based on the first offset calibration and the second offset calibration, at 606 a third offset calibration of a common mode is determined. The common mode can include a combination of the first differential pair and the second differential pair. The respective offsets (e.g., the first offset calibration, the second offset calibration, and so on) can be retained in a memory or data storage.

To determine the first offset calibration, the second offset calibration, and the third offset, (which can be performed by a comparator) the method can include controlling a back gate bias of the first transistor and the second transistor of the first differential pair and the third transistor and the fourth transistor of the second differential pair.

According to an implementation, the method can include biasing the circuit using a proportional to absolute temperature (Ptat) current. According to an additional, or alternative, implementation, the method can include biasing the circuit using a proportional to absolute temperature (Ptat) current.

In an example, the first offset calibration can be determined during a first time period when no signals are applied at the first differential pair. Further, the second offset calibration can be determined during a second time period when no signals are applied at the second differential pair.

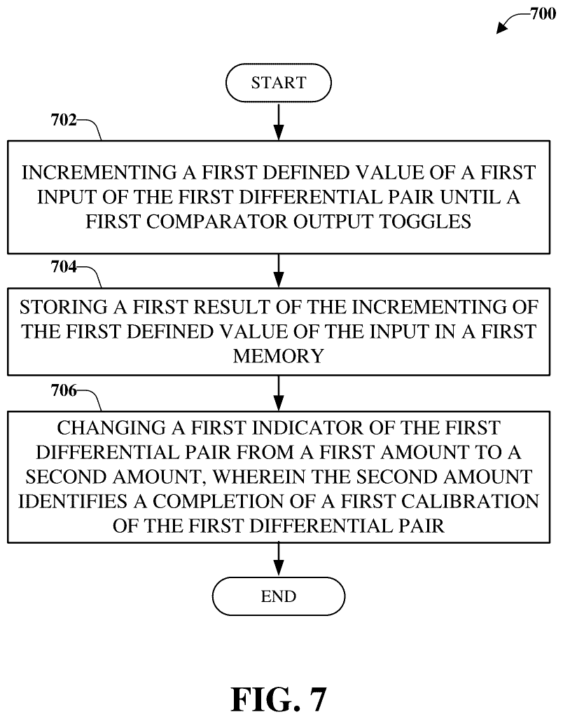

FIG. 7 illustrates an example, non-limiting, flow diagram for a method 700 for calibration of a first differential pair in accordance with one or more embodiments described herein. At 702, a first defined value of a first input of the first differential pair is incremented until a first comparator output toggles. For example, an input gate of the DAC (dacGateIn) can be incremented starting from 31 (or another value) until the comparator output toggles.

At 704, a first result of the incrementing of the first defined value of the input can be stored in a first memory. For example, the result can be stored in a data store or memory, such as a calibration differential pair one memory (nCalDiff1mem).

Further, at 706, a first indicator of the first differential pair can be changed from a first amount to a second amount. The second amount can identify a completion of a first calibration of the first differential pair. For example, at 706 it is asserted that the calibration of the first differential pair is completed, such as by setting a value to 1 (calibrationDiffPair1 Done=1).

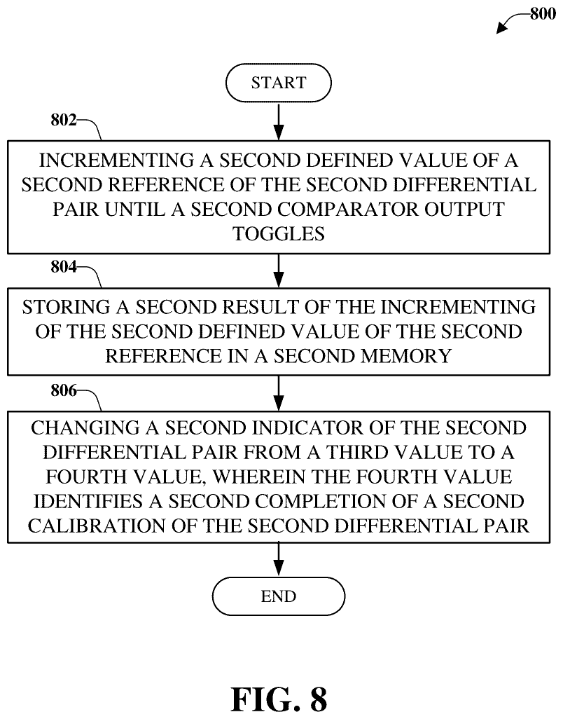

FIG. 8 illustrates an example, non-limiting, flow diagram for a method 800 for calibration of a second differential pair in accordance with one or more embodiments described herein. At 802, a second defined value of a second reference of the second differential pair can be incremented until a second comparator output toggles. For example, a reference gate of the DAC (dacGateRef) can be incremented starting from 31 (or another value) until the comparator output toggles.

At 804, a second result of the incrementing of the second defined value of the second reference can be stored in a second memory. For example, the second result can be stored in a data store or memory, such as a calibration differential pair two memory (nCalDiff2em). Thus, the first result and the second result can be retained in different memories.

Further, at 806, a second indicator of the second differential pair can be changed from a third value to a fourth value. The fourth value can identify a second completion of a second calibration of the second differential pair. For example, at 806 it can be asserted that the calibration of the second differential pair is completed, such as by setting a value to 1 (calibrationDiffPair2Done=1).

Methods that can be implemented in accordance with the disclosed subject matter will be better appreciated with reference to the above flow charts. While, for purposes of simplicity of explanation, the methods are shown and described as a series of acts or blocks, it is to be understood and appreciated that the disclosed aspects are not limited by the number or order of blocks, as some blocks can occur in different orders and/or at substantially the same time with other blocks from what is depicted and described herein. Moreover, not all illustrated blocks can be required to implement the disclosed methods. It is to be appreciated that the functionality associated with the blocks can be implemented by software, hardware, a combination thereof, or any other suitable means (e.g., device, system, process, component, and so forth). Additionally, it should be further appreciated that the disclosed methods are capable of being stored on an article of manufacture to facilitate transporting and transferring such methods to various devices. Those skilled in the art will understand and appreciate that the methods could alternatively be represented as a series of interrelated states or events, such as in a state diagram.

Reference throughout this specification to “one embodiment,” “an embodiment,” “an example,” “a disclosed aspect,” or “an aspect” means that a particular feature, structure, or characteristic described in connection with the embodiment or aspect is included in at least one embodiment or aspect of the present disclosure. Thus, the appearances of the phrase “in one embodiment,” “in one aspect,” or “in an embodiment,” in various places throughout this specification are not necessarily all referring to the same embodiment. Furthermore, the particular features, structures, or characteristics may be combined in any suitable manner in various disclosed embodiments.

As utilized herein, terms “component,” “system,” “engine,” “architecture” and the like are intended to refer to a computer or electronic-related entity, either hardware, a combination of hardware and software, software (e.g., in execution), or firmware. For example, a component can be one or more transistors, a memory cell, an arrangement of transistors or memory cells, a gate array, a programmable gate array, an application specific integrated circuit, a controller, a processor, a process running on the processor, an object, executable, program or application accessing or interfacing with semiconductor memory, a computer, or the like, or a suitable combination thereof. The component can include erasable programming (e.g., process instructions at least in part stored in erasable memory) or hard programming (e.g., process instructions burned into non-erasable memory at manufacture).

By way of illustration, both a process executed from memory and the processor can be a component. As another example, an architecture can include an arrangement of electronic hardware (e.g., parallel or serial transistors), processing instructions and a processor, which implement the processing instructions in a manner suitable to the arrangement of electronic hardware. In addition, an architecture can include a single component (e.g., a transistor, a gate array, . . . ) or an arrangement of components (e.g., a series or parallel arrangement of transistors, a gate array connected with program circuitry, power leads, electrical ground, input signal lines and output signal lines, and so on). A system can include one or more components as well as one or more architectures. One example system can include a switching block architecture comprising crossed input/output lines and pass gate transistors, as well as power source(s), signal generator(s), communication bus(ses), controllers, I/O interface, address registers, and so on. It is to be appreciated that some overlap in definitions is anticipated, and an architecture or a system can be a stand-alone component, or a component of another architecture, system, etc.

In addition to the foregoing, the disclosed subject matter can be implemented as a method, apparatus, or article of manufacture using typical manufacturing, programming or engineering techniques to produce hardware, firmware, software, or any suitable combination thereof to control an electronic device to implement the disclosed subject matter. The terms “apparatus” and “article of manufacture” where used herein are intended to encompass an electronic device, a semiconductor device, a computer, or a computer program accessible from any computer-readable device, carrier, or media. Computer-readable media can include hardware media, or software media. In addition, the media can include non-transitory media, or transport media. In one example, non-transitory media can include computer readable hardware media. Specific examples of computer readable hardware media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick, key drive . . . ). Computer-readable transport media can include carrier waves, or the like. Of course, those skilled in the art will recognize many modifications can be made to this configuration without departing from the scope or spirit of the disclosed subject matter.

What has been described above includes examples of the subject innovation. It is, of course, not possible to describe every conceivable combination of components or methodologies for purposes of describing the subject innovation, but one of ordinary skill in the art can recognize that many further combinations and permutations of the subject innovation are possible. Accordingly, the disclosed subject matter is intended to embrace all such alterations, modifications and variations that fall within the spirit and scope of the disclosure. Furthermore, to the extent that a term “includes”, “including”, “has” or “having” and variants thereof is used in either the detailed description or the claims, such term is intended to be inclusive in a manner similar to the term “comprising” as “comprising” is interpreted when employed as a transitional word in a claim.

Moreover, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Additionally, some portions of the detailed description have been presented in terms of algorithms or process operations on data bits within electronic memory. These process descriptions or representations are mechanisms employed by those cognizant in the art to effectively convey the substance of their work to others equally skilled. A process is here, generally, conceived to be a self-consistent sequence of acts leading to a desired result. The acts are those requiring physical manipulations of physical quantities. Typically, though not necessarily, these quantities take the form of electrical and/or magnetic signals capable of being stored, transferred, combined, compared, and/or otherwise manipulated.

It has proven convenient, principally for reasons of common usage, to refer to these signals as bits, values, elements, symbols, characters, terms, numbers, or the like. It should be borne in mind, however, that all of these and similar terms are to be associated with the appropriate physical quantities and are merely convenient labels applied to these quantities. Unless specifically stated otherwise or apparent from the foregoing discussion, it is appreciated that throughout the disclosed subject matter, discussions utilizing terms such as processing, computing, calculating, determining, or displaying, and the like, refer to the action and processes of processing systems, and/or similar consumer or industrial electronic devices or machines, that manipulate or transform data represented as physical (electrical and/or electronic) quantities within the registers or memories of the electronic device(s), into other data similarly represented as physical quantities within the machine and/or computer system memories or registers or other such information storage, transmission and/or display devices.

Other than in the operating examples, if any, or where otherwise indicated, all numbers, values and/or expressions referring to parameters, measurements, conditions, etc., used in the specification and claims are to be understood as modified in all instances by the term “about.”

In regard to the various functions performed by the above described components, architectures, circuits, processes and the like, the terms (including a reference to a “means”) used to describe such components are intended to correspond, unless otherwise indicated, to any component which performs the specified function of the described component (e.g., a functional equivalent), even though not structurally equivalent to the disclosed structure, which performs the function in the herein illustrated exemplary aspects of the embodiments. In addition, while a particular feature may have been disclosed with respect to only one of several implementations, such feature may be combined with one or more other features of the other implementations as may be desired and advantageous for any given or particular application. It will also be recognized that the embodiments include a system as well as a computer-readable medium having computer-executable instructions for performing the acts and/or events of the various processes.

What is claimed is:

1. A method, comprising:
determining a first offset calibration of a first differential pair of a circuit, the first differential pair comprises a first transistor and a second transistor;
determining a second offset calibration of a second differential pair of the circuit, the second differential pair comprises a third transistor and a fourth transistor; and
based on the first offset calibration and the second offset calibration, determining a third offset calibration of a common mode, wherein the common mode comprises a combination of the first differential pair and the second differential pair.

2. The method of claim 1, wherein the determining the first offset calibration comprises comparing a first current at a positive side of the first differential pair and a second current at a negative side of the first differential pair, and
wherein the determining the second offset calibration comprises comparing a third current at a positive side of the second differential pair and a fourth current at a negative side of the second differential pair.

3. The method of claim 1, wherein the determining the first offset calibration, the determining the second offset calibration, and the determining the third offset calibration comprises controlling respective back gate biases of the first transistor and the second transistor of the first differential pair and the third transistor and the fourth transistor of the second differential pair.

4. The method of claim 1, wherein the determining the first offset calibration comprises determining the first offset calibration during a first time period when no signals are applied at the first differential pair, and wherein the determining the second offset calibration comprises determining the second offset calibration during a second time period when no signals are applied at the second differential pair.

5. The method of claim 1, wherein a bias current is shared by the first differential pair and the second differential pair.

6. The method of claim 1, wherein the first differential pair is configured to receive a reference level voltage, and wherein the second differential pair is configured to receive a signal.

7. The method of claim 6, wherein the reference level voltage is a DC voltage, and wherein the signal is an alternating voltage.

8. The method of claim 1, further comprising:
biasing the circuit using a constant to absolute temperature (Ctat) current.

9. The method of claim 1, further comprising:
biasing the circuit using a proportional to absolute temperature (Ptat) current.

10. The method of claim 1, further comprising:
storing the first offset calibration in a first memory structure; and
storing the second offset calibration in a second memory structure.

11. The method of claim 1, wherein the determining the first offset calibration, the determining the second offset calibration, and the determining the third offset calibration is performed by a comparator.

12. A method, comprising:
calibrating a first differential pair of a peak detector circuit;
calibrating a second differential pair of the peak detector circuit independent of the calibrating of the first differential pair; and
calibrating a common mode of the peak detector circuit.

13. The method of claim 12, wherein the calibrating of the first differential pair comprises:
incrementing a first defined value of a first input of the first differential pair until a first comparator output toggles;
storing a first result of the incrementing of the first defined value of the first input in a first memory; and
changing a first indicator of the first differential pair from a first amount to a second amount, wherein the second amount identifies a completion of a first calibration of the first differential pair.

14. The method of claim 13, wherein the calibrating of the second differential pair comprises:
incrementing a second defined value of a second reference of the second differential pair until a second comparator output toggles;
storing a second result of the incrementing of the second defined value of the second reference in a second memory; and
changing a second indicator of the second differential pair from a third value to a fourth value, wherein the fourth value identifies a second completion of a second calibration of the second differential pair.

15. The method of claim 12, further comprising:
biasing the peak detector circuit using a proportional to absolute temperature (Ptat) current.

16. The method of claim 12, further comprising:
biasing the peak detector circuit using a constant to absolute temperature (Ctat) current.

17. The method of claim 12, wherein the calibrating the first differential pair comprises determining a first offset calibration of the first differential pair during a first time period when no signals are applied at the first differential pair, and wherein the calibrating the second differential pair comprises determining a second offset calibration of the second differential pair during a second time period when no signals are applied at the second differential pair.

18. The method of claim 17, further comprising:
retaining the first offset calibration in a first memory; and
retaining the second offset calibration in a second memory.

19. The method of claim 12, further comprising:
controlling a back gate bias of a first transistor and a second transistor of the first differential pair and a third transistor and a fourth transistor of the second differential pair.

20. The method of claim 12, wherein the calibrating the first differential pair comprises comparing a first current at a positive side of the first differential pair and a second current at a negative side of the first differential pair, and
wherein the calibrating the second differential pair comprises comparing a third current at a positive side of the second differential pair and a fourth current at a negative side of the second differential pair.
